(19) United States
(12) Patent Application Publication
(10) Pub. No.: US 2006/0145571 A1
(43) Pub. Date: Jul. 6, 2006

(54) Piezoelectric transformer provided with internal copper electrodes

(76) Inventor: Alexander Glazunov, Deutschlandsberg (AT)

Correspondence Address: FISH & RICHARDSON PC, P.O. BOX 1022, MINNEAPOLIS, MN, 55440-1022, US

(21) Appl. No.: 10/529,065

(22) PCT Filed: Sep. 29, 2003
(86) PCT No.: PCT/DE03/03239

§ 371 Date: Oct. 24, 2005

(30) Foreign Application Priority Data
Sep. 27, 2002 (DE) 102 45 130.3

(51) Int. Cl. H01L 41/107

(52) U.S. Cl. 310/359

(57) ABSTRACT

The invention concerns a piezoelectric transformer with at least two ceramic elements and a copper-bearing electrode located between the two ceramic elements. The invention recommends to choose the ceramic elements from a compound containing Pb(ZrₓTi₁₋ₓ)O₃+y Pb(Mn_{1/3}Nb_{2/3})O₃.

The subject invention concerns a multi-layer piezoelectric transformer containing a lead zirconate titanate, Pb(ZrₓTi₁₋ₓ)O₃ or PZT, ceramic body and internal copper electrodes, as well as a method for manufacturing such a transformer.

Piezoelectric transformers were invented in the year 1954 by Rosen et al. (U.S. Pat. No. 2,830,274). The way they mainly work is by first converting an electrical input signal into mechanical oscillations of the transformer body and then converting the energy of the mechanical oscillations back into an electrical output signal. The double energy conversion is accomplished using the piezoelectric effect. The effect of the transformer, i.e. the rise in voltage, is achieved by taking advantage of the properties of the ceramic material such as the mechanical quality factor Qₘ, the electromechanical coupling coefficient kᵢⱼ, and the structure of the transformer such as the electrode gap in its primary and secondary part.

Since then a large number of technical articles were published and a large number of patents were granted all over the world which all have the following goals: (i) new designs of piezoelectric transformers, (ii) new piezoelectric materials for use in transformers, and (iii) electronic circuits containing piezoelectric transformers. Multi-layer piezoelectric transformers, in particular, were developed consisting of piezoelectric ceramics that are sintered jointly with internal metal electrodes. The advantage of the multi-layer design is the possibility to enhance the voltage rise ratio by adjusting the distance between the internal electrodes in the primary or secondary part.

Thus for a specified voltage rise ratio, the size of the transformer can be reduced using the multi-layer structure.

This strong interest in piezoelectric transformers can be explained with the belief that these components can replace electromagnetic transformers in many applications, first and foremost wherever comparatively little is needed in terms of power, below 20 W, and the transformer is supposed to be small. Such applications include (i) backlighting inverters for liquid-crystal displays in laptop computers and recently “hand-held organizers”, video and photo cameras, (ii) ballasts for fluorescent bulbs and (iii) AC/DC converters for cell phones, laptops and other rechargeable hand-held devices.

The following advantages of piezoelectric transformers over electromagnetic ones are mentioned:

(i) high power density of the piezoelectric material making it possible to design a compact transformer with small dimensions, in particular thinner than electromagnetic transformers;

(ii) low energy loss and thus a more highly efficient transformer. In contrast to electromagnetic transformers, piezoelectric transformers do not contain wiring in the primary and secondary part and therefore do not suffer wiring-related losses such as losses through induced currents and the skin effect in metals;

(iii) greater reliability due to the reduced risk of a short circuit between the primary and the secondary part because there is no wiring;

(iv) piezoelectric transformers do not generate electromagnetic noise and therefore do not interfere with adjacent circuits that might be sensitive to magnetic fields.

In spite of the above-mentioned technical advantages of piezoelectric transformers, electromagnetic transformers have a significant advantage: low manufacturing costs due to the production of a large numbers of units over a long period of time, with noticeably lower manufacturing costs than those of multi-layer piezoelectric transformers. The comparatively high manufacturing costs of piezoelectric transformers are to a large extent dictated by the costs for expensive metal electrodes made typically of platinum or a silver/palladium alloy. Such expensive metals are needed for the joint sintering with PZT ceramics at high temperatures ranging from 1100 to 1200° C. that are necessary in order to manufacture dense PZT ceramics with good properties such as high piezoelectric coupling coefficients.

In order to facilitate the joint sintering of ceramic materials with electrodes made of inexpensive metals such as silver or copper, the sintering temperature of the ceramics must be lowered to below the melting point of the metal, which is 1085° C. for copper and 962° C. for silver. In addition, if copper electrodes are used, the sintering must take place in an inert atmosphere in order to prevent copper from oxidizing. The joint sintering with silver electrodes can take place in an oxidizing atmosphere (air).

At this time the following four publications can be mentioned that deal with the joint sintering of piezoelectric ceramics with copper or silver.

There are two articles that describe the method of sintering piezoelectric ceramics at 900° C., in particular the method of producing a multi-layer piezoelectric transformer with internal silver electrodes. In the U.S. Pat. No. 5,792,379, sintering is achieved at 900° C. by mixing a PZT ceramic with a specially treated glass frit composed of a combination of B₂O₃, Bi₂O₃, Cu and similar other metal oxides such as ZnO, BaO etc.

In another patent application WO 200121548 sintering is achieved at 900° C. by mixing PZT ceramics with a combination of Bi₂O₃ and CdO which have a low melting temperature and thus help in compacting the PZT ceramic. It is claimed that the advantage of using Bi₂O₃ and CdO instead of glass frit is that both Bi and Cd can be built into the crystal lattice of PZT and therefore should not form undesirable secondary phases that might be deleterious for the properties of the ceramics. In both publications a dense ceramic is achieved at 900° C. through sintering.

However, the ceramics described in these two patents had undesirable properties, in particular comparatively low values for the electromagnetic coupling coefficients kp=0.45-0.47, the mechanical quality factors Qₘ=500-650 and dielectric constants ε₃₃=400-550. The low values of these material parameters may result in undesirable transformer characteristics such as a low voltage rise ratio, low power output and low efficiency. Such undesirable properties of the ceramics may be the result of sintering the ceramics at low temperatures of 900° C. The crystalline growth could be restricted, especially at low temperatures, and low diffusion rates could not ensure a homogeneous distribution of zirconium and titanium in the PZT crystal lattice.

In view of the above, joint sintering with copper electrodes seems to be the better technological option for manufacturing high-performance multi-layer piezoelectric transformers, because higher sintering temperatures of 1000° C. instead of 900° C. should result in PZT ceramics with better properties.

Two patent applications can be mentioned that describe joint sintering of multi-layer piezoelectric ceramic components with internal copper electrodes. One of these, DE 19946834-A1, describes a multi-layer piezoelectric actuator with internal copper electrodes and a method for manufacturing same. It is claimed that it is possible to manufacture multi-layer piezoelectric actuators with internal copper electrodes without, however, giving specifics as to how to achieve this.

Another patent application, DE 10062672-A1 describes multi-layer piezoelectric components with internal copper electrodes and the method for manufacturing same. First this application describes in detail the method of joint sintering of piezoelectric ceramics with internal copper electrodes resulting in components of high density and high power output. Secondly, this patent mentions multi-layer piezoelectric components in general, including also multi-layer transformers. The method for manufacturing such components is described for multi-layer piezoelectric actuators.

The main difference between piezoelectric actuators and piezoelectric transformers is that the former, in particular the actuators described in DE 10062672-A1, are made of so-called “soft” piezoelectric ceramics. “Soft” piezoelectric ceramics are obtained by doping a basic compound Pb(ZrₓTi₁₋ₓ)O₃ with few mol-% of donator admixes that are high-valence cations such as Nd³⁺ as a substitute for Pb²⁺ as described in patent application DE 10062672-A1. “Soft” piezoelectric ceramics differ in having high values of the piezoelectric charge coefficient dᵢⱼ and the dielectric constant εᵢᵢ, but also in having high dielectric and mechanical losses represented by tan δ and the reciprocal mechanical quality factor 1/Qₘ. High mechanical losses imply low mechanical quality factors Qₘ. A PZT ceramic doped with Nd has, in particular, a tan δ>2% and a Qₘ=50-70. Such values are not suitable for use in piezoelectric transformers because such transformers would have a low efficiency.

Piezoelectric transformers are normally manufactured using “hard” piezoelectric ceramics. “Hard” ceramics are obtained by doping a basic compound Pb(ZrₓTi₁₋ₓ)O₃ with few mol-% of an acceptor admix that is a high-valence cation, as well as Mn²⁺, Fe²⁺, Ne²⁺, Zn²⁺, Mg²⁺, Li²⁺ {as a substitute for Zr⁴⁺ or Ti⁴⁺} or Ag¹⁺ (as a substitute for Pb²⁺). “Hard” PZT ceramics are characterized by low mechanical (Qm=1000-2000) and dielectric (tan δ=0.3-0.4%) losses.

Until now all known compounds of “hard” piezoelectric ceramics were developed for ceramics sintered in oxidizing atmosphere (air). There was been no research done so far as to how the properties of “hard” PZT ceramics doped with such admixes change during sintering in an inert atmosphere. The patent application DE 10062672-A1 shows only the manufacture of “soft” piezoelectric ceramics. It is possible that joint sintering in an inert atmosphere is deleterious to the piezoelectric properties of “hard” PZT ceramics, which might make these ceramics unsuitable for use in piezoelectric transformers.

The subject invention describes multi-layer piezoelectric transformers manufactured by jointly sintering “hard” piezoelectric ceramics with internal copper electrodes. The use of copper electrodes must substantially reduce the manufacturing cost of transformers, which should make them more competitive in the market. This should be considered the main improvement compared with multi-layer transformers jointly sintered with silver/palladium or internal platinum electrodes.

The subject invention has an advantage over a technology in which multi-layer piezoelectric transformers are manufactured with internal silver electrodes in the sense that higher temperatures for joint sintering, namely 1000° C. versus 900° C., results in ceramics with improved properties. The reason is that higher temperatures favor crystalline growth and the homogeneous distribution of zirconium and titanium in the PZT crystal lattice.

Compared with the existing technology of multi-layer piezoelectric transformers the invention is distinguished by the fact that copper electrodes are sintered jointly with “hard” piezoelectric ceramics.

The manufacturing method, starting from powder up to jointly sintering the ceramics with copper electrodes, was described in the patent application of EPCOS, DE 10062672-A1. Compared with this work, the subject invention is novel in that “hard” piezoelectric ceramics are used instead of the “soft” ceramics described there.

Multi-layer piezoelectric transformers with internal copper electrodes have been successfully manufactured. The transformers have various designs with different shapes and different types of electrodes.

Until this point only transformers of a single design have been characterized. The characteristics of the transformer agree with the requirements of applications in AC/DC converters for which this transformer was designed.

The ceramic compound has the general formula Pb(ZrₓTi₁₋ₓ)O₃+y Pb(Mn_{1/3}Nb_{2/3})O₃. This compound is known from prior art and has the properties suitable for use in piezoelectric transformers. The design for the transformer, including the shape of the electrodes, can be chosen as needed for use by the customer for whom the transformer was manufactured. The entire process, including the removal of an inorganic binder and the adjustment of the inert atmosphere during sintering, is described in patent application DE 10062672-A1.

The invention takes advantage of the sintering step of a “hard” ceramic in an inert atmosphere at 1000° C., which results in a density of the ceramics that is greater than that of ceramics of the same chemical composition, however sintered at 1000° C. in an oxidizing atmosphere such as air. The possibility to maintain the “hard” PZT ceramic with high density by sintering in an inert atmosphere simplifies the manufacturing process of the transformer because no admixes as described in the prior art are needed. These admixes were developed in order to reduce the sintering temperature of the ceramic in an oxidizing atmosphere such as air.

Sintering in an inert atmosphere improves the properties of the “hard” piezoelectric ceramic, which is of great importance for use in piezoelectric transformers. The dielectric losses, in particular, are reduced, and the electromechanical coupling coefficient is increased compared to ceramics with the same chemical composition sintered at 1000° C. in an oxidizing atmosphere (air).

1-9. (canceled)

10. A piezoelectric transformer comprising:
ceramic layers comprising a hard piezoelectric material; and
an electrode layer comprising copper, the electrode layer being disposed between the ceramic layers.

11. The piezoelectric transformer of claim 10, wherein the hard piezoelectric material comprises ceramic green film containing a binder that is thermohydrolytically decomposable.

12. The piezoelectric transformer of claim 11, wherein the binder comprises a polyurethane dispersion.

13. The piezoelectric transformer of claim 10, wherein the hard piezoelectric material includes a general composition of Pb(ZrₓTi₁₋ₓ)O₃, wherein part of Zr or Ti is replaced by a low-valence cation having an oxidation level 1+ or 2+.

14. The piezoelectric transformer of claim 10, wherein the hard piezoelectric material includes a general composition of Pb(ZrₓTi₁₋ₓ)O₃, wherein part of Pb is replaced by a low-valence cation having an oxidation level 1+.

15. The piezoelectric transformer of claim 10, wherein the hard piezoelectric material has a general composition of Pb[(ZrₓTi₁₋ₓ)_{1-y}(Mn_{1/3}Nb_{2/3})_{y}]O₃.

16. The piezoelectric transformer of claim 10, wherein the electrode layer comprises a screen-printed electrode layer.

17. A method of producing a piezoelectric transformer comprised of (i) ceramic layers comprising a hard piezoelectric material, and (ii) an electrode layer comprising copper, the electrode layer being disposed between the ceramic layers, wherein the method comprises:
sintering the hard piezoelectric ceramic in an inert atmosphere.

18. The method of claim 17, wherein the ceramic is sintered at a temperature that is below the melting point of copper.

19. The method of claim 17, wherein the hard piezoelectric material comprises ceramic green film containing a binder that is thermohydrolytically decomposable.

20. The method of claim 19, wherein the binder comprises a polyurethane dispersion.

21. The method of claim 17, wherein the hard piezoelectric material has a general composition of Pb(ZrₓTi₁₋ₓ)O₃, wherein part of Zr or Ti is replaced by a low-valence cation having an oxidation level 1+ or 2+.

22. The method of claim 17, wherein the hard piezoelectric material has a general composition of Pb(ZrₓTi₁₋ₓ)O₃, wherein part of Pb is replaced by a low-valence cation having an oxidation level 1+.

23. The method of claim 17, wherein the hard piezoelectric material has a general composition of Pb[(ZrₓTi₁₋ₓ)_{1-y}(Mn_{1/3}Nb_{2/3})_{y}]O₃.

24. The method of claim 17, wherein the electrode layer comprises a screen-printed electrode layer.

25. The method of claim 17, wherein sintering occurs at a temperature of about 1000° C.

26. The method of claim 17, wherein the electrode layer contains no precious metal.

27. An AC/DC converter comprising:
a piezoelectric transformer comprising:
ceramic layers comprising a hard piezoelectric material, the hard piezoelectric material having a general composition of Pb[(ZrₓTi₁₋ₓ)_{1-y}(Mn_{1/3}Nb_{2/3})_{y}]O₃; and
an electrode layer comprising copper, the electrode layer being disposed between the ceramic layers;
wherein the electrode layer does not include substantial amounts of silver, palladium, or platinum.

28. The AC/DC converter of claim 27, further comprising multiple electrode layers, each of the multiple electrode layers being between ceramic layers, each of the multiple electrode layers comprising copper and not including substantial amounts of silver, palladium, or platinum.

29. The AC/DC converter of claim 27, wherein the hard piezoelectric material has a general composition of Pb[(ZrₓTi₁₋ₓ)_{1-y}(Mn_{1/3}Nb_{2/3})_{y}]O₃.

30. The AC/DC converter of claim 27, wherein the electrode layer comprises a screen-printed electrode layer.
